(19) United States
(12) Patent Application Publication
(10) Pub. No.: US 2026/0206183 A1
(43) Pub. Date: Jul. 16, 2026

(54) COOLING DEVICE AND ELECTRONIC COMPONENT

(71) Applicant: Fujitsu Limited, Kawasaki-shi (JP)

(72) Inventors: Hiroyuki KUBO, Kawasaki (JP); TAKASHI SHIRAKAMI, Kawasaki (JP); Yasuhisa KANEMARU, Fukuoka (JP); Akira NAKAYAMA, Kawasaki (JP)

(73) Assignee: Fujitsu Limited, Kawasaki-shi (JP)

(21) Appl. No.: 19/423,587

(22) Filed: Dec. 17, 2025

(30) Foreign Application Priority Data
Dec. 25, 2024 (JP) 2024-228674

(51) Int. Cl. H05K 7/20; H05K 1/02

(52) U.S. Cl. CPC H05K 7/20272; H05K 1/0203; H05K 7/20254; H05K 7/20263; H05K 7/20436; H05K 2201/066; H05K 2201/10121

(57) ABSTRACT

A cooling device includes a first cold plate that cools a first heat generating component, a second cold plate that cools a second heat generating component, a radiator that is provided on the second cold plate and cools a refrigerant, a first refrigerant passage that connects the first cold plate and the second cold plate, and causes the refrigerant that received heat from the first heat generating component to flow from the first cold plate into the second cold plate, and a second refrigerant passage that connects the second cold plate and the radiator and causes the refrigerant that received heat from the second heat generating component to flow from the second cold plate into the radiator.

### CROSS-REFERENCE TO RELATED APPLICATION

This application is based upon and claims the benefit of priority of Japanese Patent Application No. 2024-228674 filed on Dec. 25, 2024, the entire contents of which are incorporated herein by reference.

### FIELD

A certain aspect of the present embodiments relates to a cooling device and an electronic component.

### BACKGROUND

A cooling device that cools a heat generating component using a refrigerant is known. For example, a cooling device capable of cooling a plurality of heat generating components is known (for example, Japanese Patent Application Publication No. 2004-266247, U.S. Patent Application Publication No. 2015/0109734, U.S. Patent Application Publication No. 2012/0279233, and Japanese Patent Application Publication No. 8-279578).

### SUMMARY

According to an aspect of the present disclosure, there is provided a cooling device including: a first cold plate that cools a first heat generating component; a second cold plate that cools a second heat generating component; a radiator that is provided on the second cold plate and cools a refrigerant; a first refrigerant passage that connects the first cold plate and the second cold plate, and causes the refrigerant that received heat from the first heat generating component to flow from the first cold plate into the second cold plate; and a second refrigerant passage that connects the second cold plate and the radiator and causes the refrigerant that received heat from the second heat generating component to flow from the second cold plate into the radiator.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a perspective view of a cooling device according to a first embodiment.

FIG. 2 is an exploded perspective view of the cooling device according to the first embodiment.

FIGS. 3A and 3B are perspective views illustrating the flow of a refrigerant in the cooling device according to the first embodiment (Part 1).

FIG. 4 is a perspective view illustrating the flow of a refrigerant in the cooling device according to the first embodiment (Part 2).

FIG. 5 is a diagram illustrating an effect of the cooling device according to the first embodiment.

FIG. 6A is a perspective view of a cooling device according to a comparative example.

FIG. 6B is a perspective view of a lower member of a cold plate in the comparative example.

FIG. 7A is a schematic plan view of a cooling device according to the comparative example when the cooling device is disposed on a first heat generating component and a second heat generating component.

FIG. 7B is a schematic plan views of the cooling devices according to the first embodiment when the cooling device is disposed on a first heat generating component and a second heat generating component.

FIG. 8 is a perspective view of a cooling device according to a second embodiment.

FIGS. 9A and 9B are perspective views illustrating the flow of the refrigerant in the cooling device according to the second embodiment.

FIG. 10 is a diagram illustrating an effect of the cooling device according to the second embodiment.

FIGS. 11A and 11B are perspective views of lower member of second cold plates in a third embodiment and a modification of the third embodiment, respectively.

FIG. 12 is a perspective view of a cooling device according to a fourth embodiment.

FIG. 13A is a perspective view of a cooling device according to a fifth embodiment as viewed from a −Y direction.

FIG. 13B is a perspective view of the cooling device according to the fifth embodiment as viewed from a +Y direction.

FIG. 14A is a perspective view of a cooling device according to a modification of the fifth embodiment as viewed from the −Y direction.

FIG. 14B is a perspective view of the cooling device according to the modification of the fifth embodiment as viewed from the +Y direction.

FIG. 15A is an external perspective view of an electronic component according to a sixth embodiment.

FIG. 15B is a plan view of a substrate provided inside a housing.

### DESCRIPTION OF EMBODIMENTS

As a cooling method having excellent cooling characteristics, boiling cooling (i.e., two-phase cooling) using latent heat of evaporation of a refrigerant is known. The refrigerant that is brought into a gas-liquid mixture by the boiling cooling is sent to a radiator, cooled, and returned to a liquid. It is desirable that the cooling device uses the boiling cooling in order to improve cooling performance, but on the other hand, it is also desirable that the cooling device is miniaturized so as to be able to be disposed in a limited space for miniaturization of electronic components and the like.

In one aspect, an object is to enable improvement in cooling performance and miniaturization.

Hereinafter, embodiments of the present disclosure will be described with reference to the drawings.

### First Embodiment

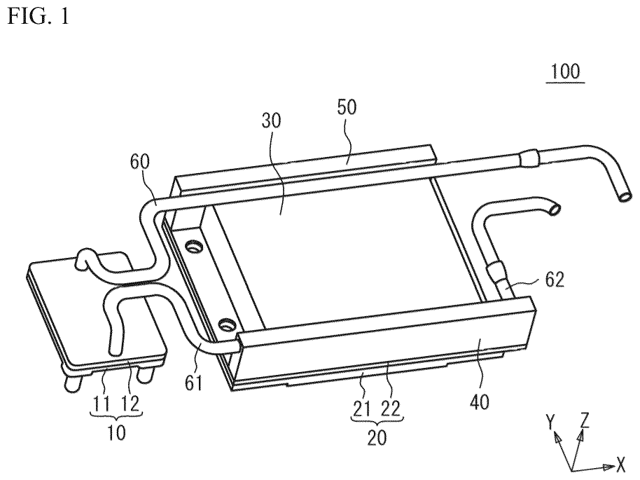

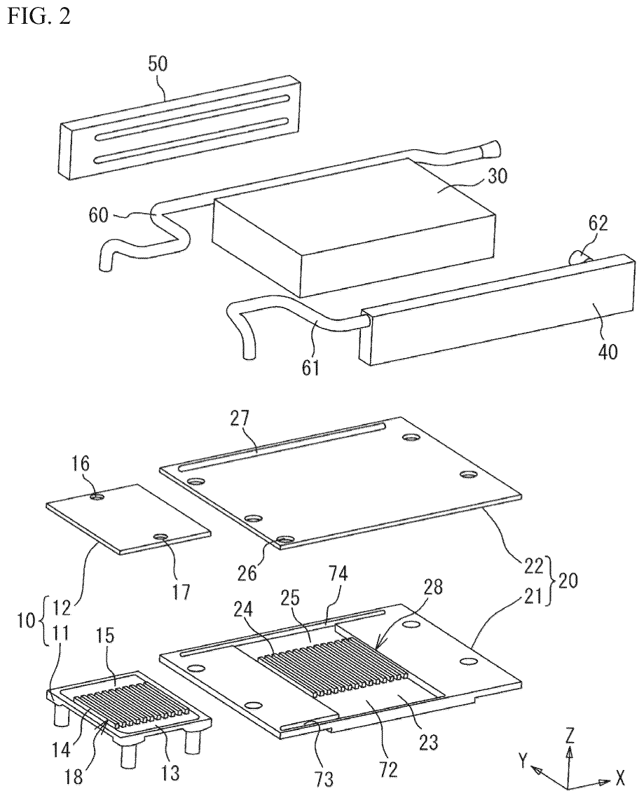

FIG. 1 is a perspective view of a cooling device 100 according to a first embodiment. FIG. 2 is an exploded perspective view of the cooling device 100 according to the first embodiment. As illustrated in FIGS. 1 and 2, the cooling device 100 according to the first embodiment includes a first cold plate 10, a second cold plate 20, a radiator 30, and a first member 40 and a second member 50 that interposes the radiator 30. Directions orthogonal to each other are illustrated as an X-axis direction, a Y-axis direction, and a Z-axis direction.

The first cold plate 10 includes a lower member 11 having a groove 13, and an upper member 12 that is in contact with an upper surface of the lower member 11 and covers the groove 13. The groove 13 is provided over most of the lower member 11, and has a substantially rectangular shape in plan view. The groove 13 serves as a flow path 15 through which a refrigerant for cooling a first heat generating component disposed below the first cold plate 10 flows. The refrigerant is, for example, a cooling liquid such as cooling water or an ethanol aqueous solution. A plurality of fins 14 are provided in the groove 13. The region where the fins 14 are provided is a heat receiving region 18 where the refrigerant receives heat from the first heat generating component. A through hole 16 is provided at an end of the upper member 12 in the +Y direction, and a through hole 17 is provided at an end of the upper member 12 in the −Y direction. The through holes 16 and 17 are located above the groove 13 and communicate with the groove 13. A pipe 60 is connected to the through hole 16, and a pipe 61 is connected to the through hole 17. The first cold plate 10 is formed of a metal such as copper, aluminum, or stainless steel. The pipes 60 and 61 may be formed of a metal such as copper or aluminum, or may be formed of a nonmetal such as a resin.

The second cold plate 20 includes a lower member 21 having a groove 23, and an upper member 22 that is in contact with an upper surface of the lower member 21 and covers the groove 23. The groove 23 includes a flow passage portion 72, an inflow portion 73, and an outflow portion 74. The inflow portion 73 is provided to extend in the X-axis direction at the end of the lower member 21 in the −Y direction. The outflow portion 74 is provided to extend in the X-axis direction at the end of the lower member 21 in the +Y direction. The flow passage portion 72 is provided so as to connect the inflow portion 73 and the outflow portion 74. The groove 23 serves as a flow path 25 through which a refrigerant for cooling a second heat generating component disposed below the second cold plate 20 flows. The flow passage portion 72 has a substantially rectangular shape in plan view, and is provided with a plurality of fins 24. The region where the fins 24 are provided is a heat receiving region 28 where the refrigerant receives heat from the second heat generating component. The upper member 22 is provided with a through hole 26 located above the inflow portion 73 and communicating with the inflow portion 73, and a through hole 27 located above the outflow portion 74, communicating with the outflow portion 74, and elongated in the X-axis direction. The second cold plate 20 is formed of a metal such as copper, aluminum, or stainless steel.

The radiator 30 is provided on the second cold plate 20. The radiator 30 is smaller than the second cold plate 20 when viewed from the +Z direction, and is accommodated inside the upper surface of the second cold plate 20. The radiator 30 has a function of cooling the refrigerant flowing through the groove 13 of the first cold plate 10 and the groove 23 of the second cold plate 20 by exchanging heat with air.

The first member 40 and the second member 50 are provided on the second cold plate 20 with the radiator 30 interposed therebetween in the Y-axis direction. The first member 40 and the second member 50 are, for example, plate-shaped members. The first member 40 is connected to an end of the radiator 30 in the −Y direction, and the second member 50 is connected to an end of the radiator 30 in the +Y direction. For example, the radiator 30 is supported by the first member 40 and the second member 50, and a gap is formed between the radiator 30 and the second cold plate 20. The first member 40 and the second member 50 may be formed of a metal such as copper or aluminum, or may be formed of a nonmetal such as a resin.

The pipe 61 is connected to the end of the first member 40 in the-X direction. A pipe 62 is connected to the end of the first member 40 in the +X direction.

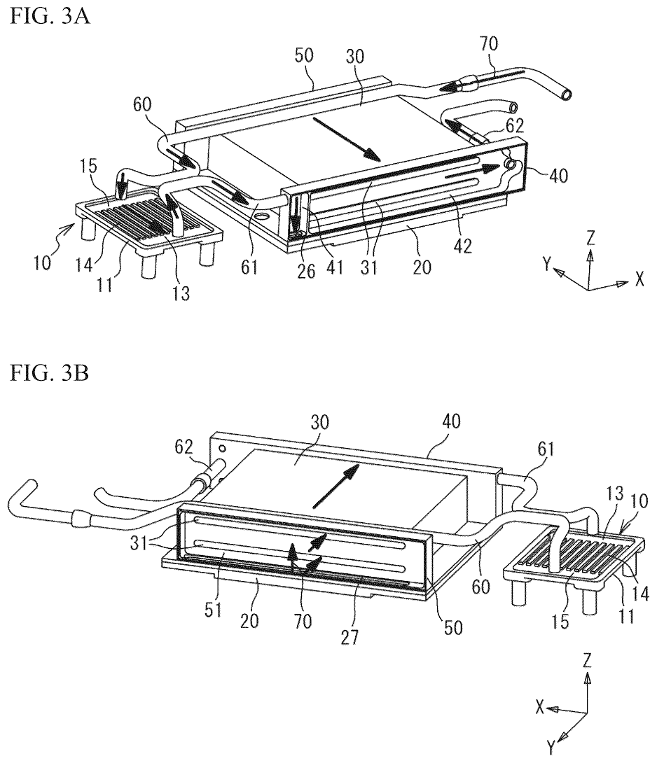

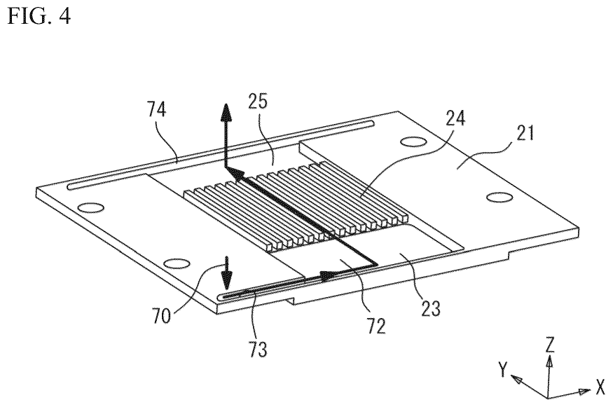

FIGS. 3A, 3B, and 4 are perspective views illustrating the flow of a refrigerant 70 in the cooling device 100 according to the first embodiment. FIG. 3A is a perspective view of the cooling device 100 according to the first embodiment as viewed from the −Y direction, and FIG. 3B is a perspective view of the cooling device 100 as viewed from the +Y direction. FIG. 4 is a perspective view of the lower member 21 of the second cold plate 20 in the first embodiment. FIG. 3A illustrates the inside of the first member 40 and the inside of the first cold plate 10 in a see-through manner, and FIG. 3B illustrates the inside of the second member 50 and the inside of the first cold plate 10 in a see-through manner. As illustrated in FIG. 3A, the inside of the first member 40 is divided into a space 41 and a space 42. As illustrated in FIG. 3B, the inside of the second member 50 is one space 51.

As illustrated in FIG. 3A, the refrigerant 70 (indicated by arrows) supplied to one end of the pipe 60 flows through the pipe 60 and flows into the first cold plate 10 to which the other end of the pipe 60 is connected. The refrigerant 70 flowed into the first cold plate 10 flows through the groove 13 of the lower member 11 from the +Y direction toward the −Y direction.

Since the pipe 61 is connected to the end of the first cold plate 10 in the −Y direction, the refrigerant 70 flowing through the groove 13 in the −Y direction flows into the pipe 61. The pipe 61 is also connected to the space 41 of the first member 40. Therefore, the refrigerant 70 flowed into the pipe 61 flows into the space 41 of the first member 40. The space 41 communicates with the through hole 26 provided in the upper member 22 of the second cold plate 20. Therefore, as illustrated in FIGS. 3A and 4, the refrigerant 70 flowed into the space 41 flows into the inflow portion 73 of the lower member 21 of the second cold plate 20 through the through hole 26. The refrigerant 70 flowed into the inflow portion 73 flows through the flow passage portion 72 from the −Y direction toward the +Y direction.

As illustrated in FIGS. 3B and 4, the space 51 of the second member 50 communicates with the through hole 27 provided in the upper member 22 of the second cold plate 20. Therefore, the refrigerant 70 flowing through the flow passage portion 72 toward the +Y direction flows into the space 51 of the second member 50 from the outflow portion 74 via the through hole 27.

As illustrated in FIGS. 3A and 3B, one ends of tubes 31 of the radiator 30 are connected to the space 51. The other ends of the tubes 31 are connected to the space 42 of the first member 40. Therefore, the refrigerant 70 flows from the space 51 of the second member 50 through the radiator 30 from the +Y direction toward the −Y direction, and flows into the space 42 of the first member 40. One end of the pipe 62 is connected to the space 42. Therefore, the refrigerant 70 flowed into the space 42 flows through the pipe 62 and is discharged from the other end of the pipe 62.

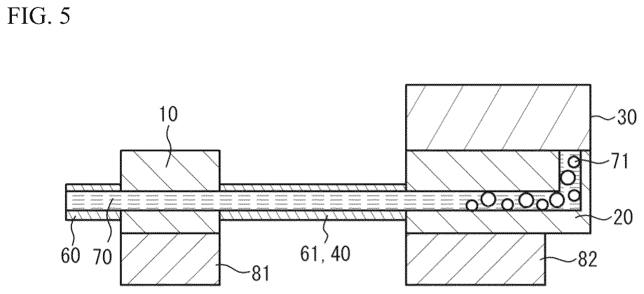

FIG. 5 is a diagram illustrating an effect of the cooling device 100 according to the first embodiment. As illustrated in FIG. 5, the first cold plate 10 is used to cool a first heat generating component 81, and the second cold plate 20 is used to cool a second heat generating component 82. For example, an amount of heat generated by the second heat generating component 82 is larger than an amount of heat generated by the first heat generating component 81. The refrigerant 70 flowed into the first cold plate 10 from the pipe 60 receives heat from the first heat generating component 81, and thus the temperature of the refrigerant 70 increases. After receiving heat from the first heat generating component 81, the refrigerant 70 flows from the first cold plate 10 through the pipe 61 and the first member 40, and flows into the second cold plate 20.

The refrigerant 70 receives heat from the second heat generating component 82 in the second cold plate 20, and the temperature of the refrigerant 70 further increases. Therefore, the refrigerant 70 is likely to cause a boiling phenomenon in the second cold plate 20. The gas generated by boiling of the refrigerant 70 is illustrated as a gas 71. In this way, the refrigerant 70 whose temperature is increased by receiving heat from the first heat generating component 81 flows into the second cold plate 20, and thus the temperature of the refrigerant 70 further increases due to the heat received from the second heat generating component 82 in the second cold plate 20. Accordingly, since the boiling phenomenon of the refrigerant 70 is promoted in the second cold plate 20, the cooling performance for the second heat generating component 82 is improved by the boiling cooling (i.e., two-phase cooling) using the latent heat of evaporation.

The refrigerant 70 that has become a gas-liquid mixture flows into the radiator 30 on the second cold plate 20 and is cooled to return to a liquid. Since the radiator 30 that cools the gas-liquid mixed refrigerant 70 is provided on the second cold plate 20, the cooling device 100 can be downsized as compared with a case where the radiator 30 is provided at a place other than on the second cold plate 20.

### Comparative Example

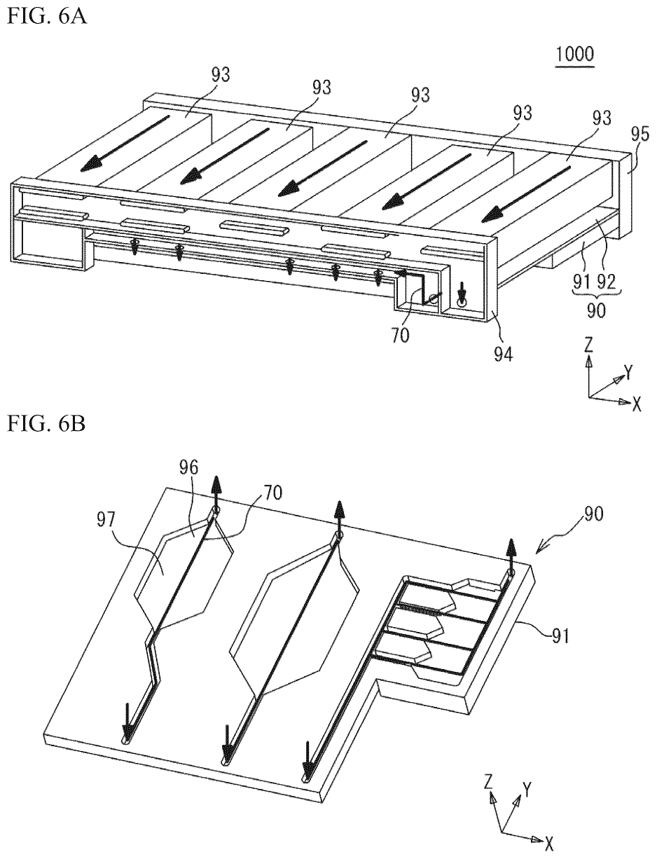

FIG. 6A is a perspective view of a cooling device 1000 according to a comparative example, and FIG. 6B is a perspective view of a lower member 91 of a cold plate 90 in the comparative example. In FIG. 6A, the inside of the member 94 is illustrated in a see-through manner. In FIGS. 6A and 6B, the flow of the refrigerant 70 is also indicated by arrows. As illustrated in FIGS. 6A and 6B, the cooling device 1000 according to the comparative example includes the cold plate 90, a plurality of radiators 93, and a member 94 and a member 95 that interpose the plurality of radiators 93. The plurality of radiators 93 are provided on the cold plate 90.

The cold plate 90 includes the lower member 91 having a plurality of grooves 96, and an upper member 92 that is in contact with the upper surface of the lower member 91 and covers the grooves 96. The groove 96 serves as a flow path 97 through which the refrigerant 70 flows. The refrigerant 70 flows from the member 94 into the groove 96 and flows through the groove 96 from the −Y direction toward the +Y direction. The refrigerant 70 flowing through the groove 96 toward the +Y direction flows into the member 95. The refrigerant 70 flowed into the member 95 flows through the plurality of radiators 93, then flows into the member 94, and is discharged from the member 94 to the outside.

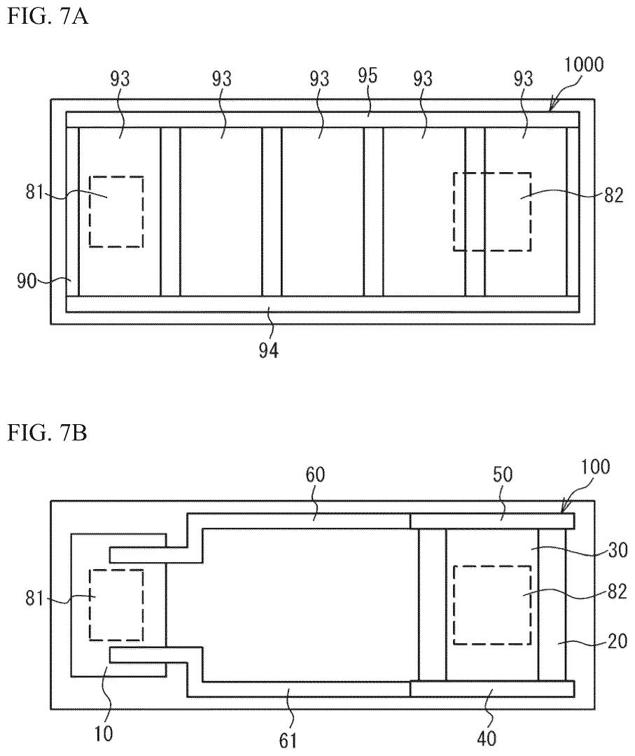

FIG. 7A is a schematic plan view of the cooling device 1000 according to the comparative example disposed on the first heat generating component 81 and the second heat generating component 82, and FIG. 7B is a schematic plan view of the cooling device 100 according to the first embodiment disposed on the first heat generating component 81 and the second heat generating component 82. As illustrated in FIG. 7A, in the comparative example, a large cold plate 90 is provided from the first heat generating component 81 to the second heat generating component 82 in order to cool the first heat generating component 81 and the second heat generating component 82. On the other hand, in the first embodiment, as illustrated in FIG. 7B, the first cold plate 10 for cooling the first heat generating component 81 is provided on the first heat generating component 81. The second cold plate 20 for cooling the second heat generating component 82 is provided on the second heat generating component 82. Accordingly, the total volume of the first cold plate 10 and the second cold plate 20 can be made smaller than that of the cold plate 90. Therefore, the cooling device 100 of the first embodiment is lighter than the cooling device 1000 of the comparative example. The first member 40 and the second member 50 in the first embodiment are shorter than the members 94 and 95 in the comparative example. In this respect, the cooling device 100 of the first embodiment is lighter than the cooling device 1000 of the comparative example.

As described above, according to the first embodiment, as illustrated in FIGS. 1 and 5, the first cold plate 10 that cools the first heat generating component 81 and the second cold plate 20 that cools the second heat generating component 82 are connected to each other by the pipe 61 and the first member 40. As illustrated in FIGS. 3A and 4, the refrigerant 70 having received heat from the first heat generating component 81 flows from the first cold plate 10 into the second cold plate 20 through the pipe 61 and the space 41 of the first member 40. Accordingly, the refrigerant 70 having received heat from the first heat generating component 81 and having an increased temperature in the first cold plate 10 receives heat from the second heat generating component 82 and has a further increased temperature in the second cold plate 20. Therefore, the boiling phenomenon of the refrigerant 70 is promoted in the second cold plate 20, and the second heat generating component 82 can be cooled by the boiling cooling using the latent heat of vaporization of the refrigerant 70. Therefore, the cooling performance for the second heat generating component 82 can be improved. The pipe 61 and the space 41 of the first member 40 are a first refrigerant passage through which the refrigerant 70 having received heat from the first heat generating component 81 flows from the first cold plate 10 into the second cold plate 20.

As illustrated in FIG. 1, the radiator 30 is provided on the second cold plate 20. The second cold plate 20 and the radiator 30 are connected by the second member 50. As illustrated in FIGS. 3B and 4, the refrigerant 70 having received heat from the second heat generating component 82 in the second cold plate 20 flows from the second cold plate 20 into the radiator 30 through the space 51 of the second member 50. As described above, the radiator 30 that cools the refrigerant 70 is provided on the second cold plate 20, and thus the cooling device 100 can be downsized. The space 51 of the second member 50 is a second refrigerant passage through which the refrigerant 70 having received heat from the second heat generating component 82 flows from the second cold plate 20 into the radiator 30.

In the first embodiment, as illustrated in FIG. 1, the first member 40 and the second member 50 are provided with the radiator 30 interposed therebetween. As illustrated in FIG. 3A, the first member 40 includes the space 41 (first refrigerant passage) through which the refrigerant 70 flows from the first cold plate 10 into the second cold plate 20, and the space 42 (third refrigerant passage) into which the refrigerant 70 flows from the radiator 30. The second member 50 has the space 51 (second refrigerant passage) through which the refrigerant 70 flows from the second cold plate 20 into the radiator 30. Accordingly, it is possible to obtain a configuration in which the refrigerant 70 flows through the radiator 30 on the second cold plate 20 while suppressing an increase in the size of the cooling device 100.

In addition, in the first embodiment, as illustrated in FIG. 1, the pipe 61 that connects the first cold plate 10 and the first member 40 is provided. The first refrigerant passage through which the refrigerant 70 flows from the first cold plate 10 into the second cold plate 20 is formed by the pipe 61 and the space 41 of the first member 40. Since the first cold plate 10 and the first member 40 are connected by the pipe 61, the size of the first cold plate 10 can be appropriately set according to the amount of heat generated by the first heat generating component 81. Therefore, when the amount of heat generated by the first heat generating component 81 is small, the first cold plate 10 can be made small, and the cooling device 100 can be made small and lightweight.

In the first embodiment, it is preferable that all of the first cold plate 10, the second cold plate 20, the first member 40, the second member 50, the pipe 60, the pipe 61, and the pipe 62 are formed of a metal such as copper or aluminum. In this case, the airtightness of the flow path through which the refrigerant 70 flows can be improved, and the refrigerant 70 can be sealed in the flow path in a reduced pressure state. This makes it possible to facilitate the occurrence of the boiling phenomenon of the refrigerant 70.

### Second Embodiment

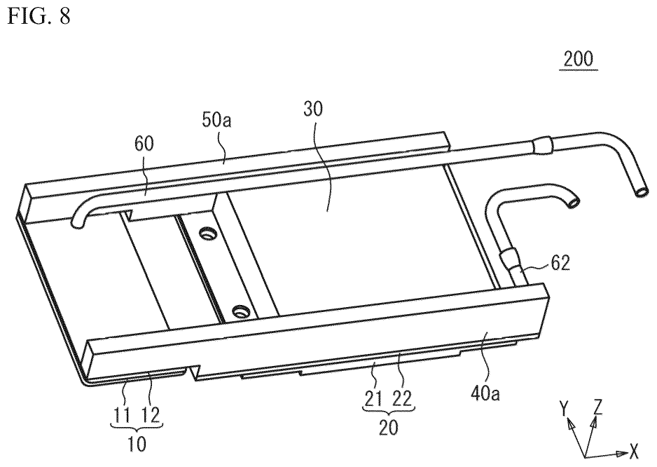

FIG. 8 is a perspective view of a cooling device 200 according to the second embodiment. As illustrated in FIG. 8, in the cooling device 200 according to the second embodiment, a first member 40a and a second member 50a are provided from the second cold plate 20 to the first cold plate 10. Therefore, a pipe connecting the first cold plate 10 and the first member 40a is not provided. The other configurations of the second embodiment are the same as those of the first embodiment, and thus the description thereof will be omitted.

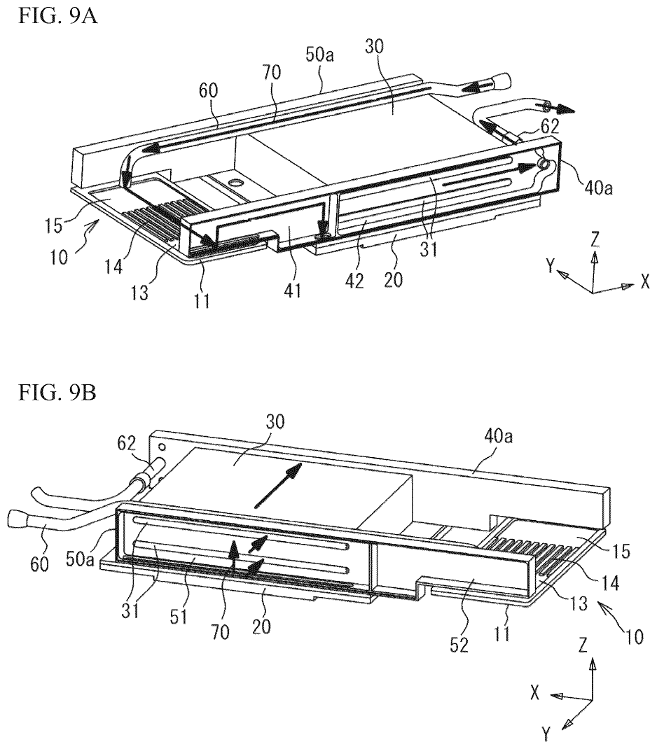

FIGS. 9A and 9B are perspective views illustrating the flow of the refrigerant 70 in the cooling device 200 according to the second embodiment. FIG. 9A is a perspective view of the cooling device 200 according to the second embodiment as viewed from the −Y direction, and FIG. 9B is a perspective view of the cooling device 200 as viewed from the +Y direction. FIG. 9A illustrates the inside of the first member 40a and the inside of the first cold plate 10 in a see-through manner. FIG. 9B illustrates the inside of the second member 50a and the inside of the first cold plate 10 in a see-through manner. As illustrated in FIG. 9A, the inside of the first member 40a is divided into the space 41 and the space 42. As illustrated in FIG. 9B, the inside of the second member 50a is divided into a space 51 and a space 52.

As illustrated in FIG. 9A, the refrigerant 70 (indicated by arrows) supplied to one end of the pipe 60 flows through the pipe 60 and flows into the first cold plate 10 to which the other end of the pipe 60 is connected. The refrigerant 70 flowed in from the pipe 60 flows through the groove 13 of the lower member 11 of the first cold plate 10 from the +Y direction toward the −Y direction.

The first member 40a is provided from the second cold plate 20 to the first cold plate 10, and the groove 13 and the space 41 of the first member 40a communicate with each other. Therefore, the refrigerant 70 flowing through the groove 13 in the −Y direction flows into the space 41 in the first member 40a. The space 41 also communicates with the inflow portion 73 (also see FIG. 4) of the lower member 21 of the second cold plate 20. Therefore, the refrigerant 70 flowed into the space 41 flows into the inflow portion 73. The refrigerant 70 flowed into the inflow portion 73 flows through the flow passage portion 72 from the −Y direction toward the +Y direction.

As illustrated in FIGS. 9B and 4, the space 51 of the second member 50a communicates with the outflow portion 74 of the lower member 21 of the second cold plate 20. Therefore, the refrigerant 70 flowing through the flow passage portion 72 toward the +Y direction flows into the space 51 of the second member 50a from the outflow portion 74. The refrigerant 70 does not flow into the space 52 of the second member 50a. The refrigerant 70 may flow through a space defined in the second member 50a instead of the pipe 60 and flow into the first cold plate 10 via the space 52.

As illustrated in FIGS. 9A and 9B, one ends of the tubes 31 of the radiator 30 are connected to the space 51. The other ends of the tubes 31 are connected to the space 42 of the first member 40a. Therefore, the refrigerant 70 flows from the space 51 of the second member 50a through the radiators 30 from the +Y direction toward the −Y direction, and flows into the space 42 of the first member 40a. One end of the pipe 62 is connected to the space 42. Therefore, the refrigerant 70 flowed into the space 42 flows through the pipe 62 and is discharged from the other end of the pipe 62.

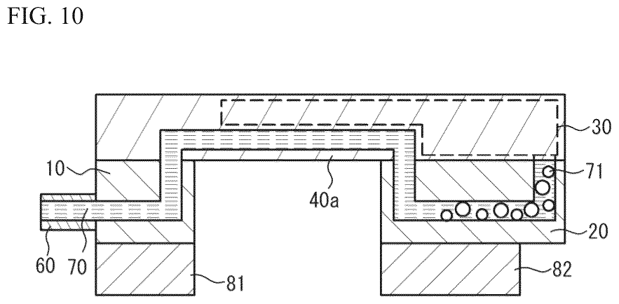

FIG. 10 is a diagram illustrating an effect of the cooling device 200 according to the second embodiment. As illustrated in FIG. 10, similarly to the first embodiment, the refrigerant 70 flowed into the first cold plate 10 from the pipe 60 receives heat from the first heat generating component 81, and thus the temperature of the refrigerant 70 increases. After receiving heat from the first heat generating component 81, the refrigerant 70 flows from the first cold plate 10 through the first member 40a and flows into the second cold plate 20. The refrigerant 70 receives heat from the second heat generating component 82 and the temperature thereof further increases. Therefore, the boiling phenomenon of the refrigerant 70 is promoted in the second cold plate 20, and the cooling performance for the second heat generating component 82 is improved by the boiling cooling using the latent heat of vaporization of the refrigerant 70.

According to the second embodiment, the refrigerant 70 having received heat from the first heat generating component 81 flows into the second cold plate 20 through the space 41 of the first member 40a. Accordingly, the refrigerant 70 whose temperature has increased by receiving heat from the first heat generating component 81 further increases in temperature by receiving heat from the second heat generating component 82 in the second cold plate 20, and thus the boiling phenomenon is promoted in the second cold plate 20. Therefore, the cooling performance for the second heat generating component 82 can be improved by the boiling cooling using the latent heat of evaporation of the refrigerant 70. Further, since the radiator 30 that cools the refrigerant 70 is provided on the second cold plate 20, the cooling device 200 can be downsized.

In addition, in the second embodiment, the first member 40a and the second member 50a are provided from the second cold plate 20 to the first cold plate 10. The first refrigerant path that allows the refrigerant 70 to flow from the first cold plate 10 into the second cold plate 20 is formed by the space 41 of the first member 40a. According to this configuration, a pipe connecting the first cold plate 10 and the first member 40a is not required, and thus the number of components can be reduced. The first member 40a and the second member 50a provided from the first cold plate 10 to the second cold plate 20 can function as ducts that allow air to flow toward the radiators 30. Therefore, the cooling performance of the radiator 30 for the refrigerant 70 can be improved.

### Third Embodiment

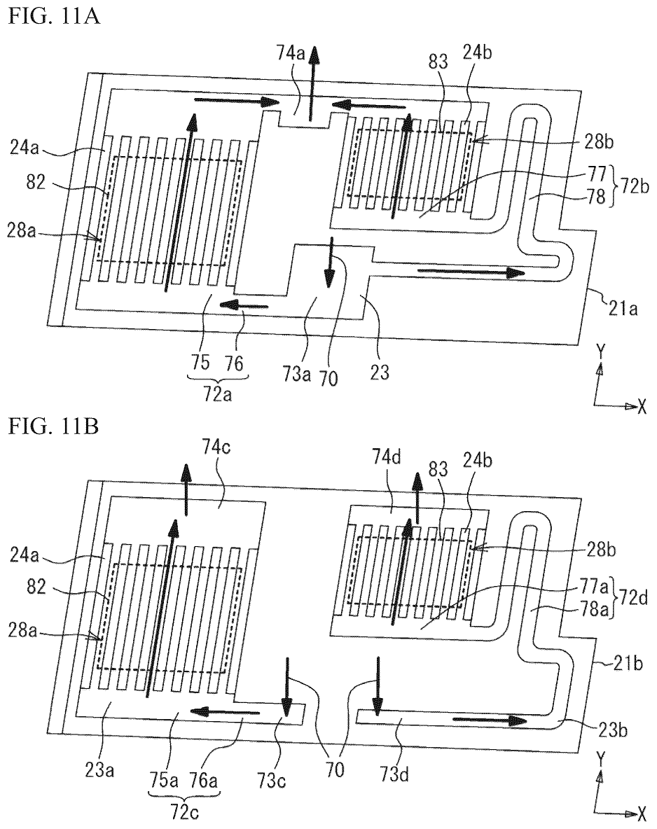

FIG. 11A is a perspective view of a lower member 21a of the second cold plate 20 in the third embodiment, and FIG. 11B is a perspective view of a lower member 21b of the second cold plate 20 in a modification of the third embodiment. FIGS. 11A and 11B also illustrate the second heat generating component 82 and a third heat generating component 83 cooled by the second cold plate 20, and the flow of the refrigerant 70.

As illustrated in FIG. 11A, in the third embodiment, the groove 23 provided in the lower member 21a has an inflow portion 73a into which the refrigerant 70 flows from the first member 40 in the vicinity of the center portion in the X-axis direction. The flow passage portion 72a and the 72b are separated from the inflow portion 73a and joined at an outflow portion 74a. The flow passage portion 72a includes a main portion 75 having a substantially rectangular shape in plan view and provided with a plurality of fins 24a, and a connecting portion 76 connecting the main portion 75 and the inflow portion 73a. A region where the fins 24a are provided is a heat receiving region 28a where the refrigerant 70 receives heat from the second heat generating component 82. Similarly, the flow passage portion 72b includes a main portion 77 having a substantially rectangular shape in plan view and provided with a plurality of fins 24b, and a connecting portion 78 connecting the main portion 77 and the inflow portion 73a. A region where the fins 24b are provided is a heat receiving region 28b where the refrigerant 70 receives heat from the third heat generating component 83. The connecting portion 76 and the connecting portion 78 are different from each other in at least one of the length and the width, for example. The other configurations of the third embodiment are the same as those of the first embodiment, and thus the description thereof will be omitted.

As illustrated in FIG. 11B, in the modification of the third embodiment, two grooves 23a and 23b are provided in the lower member 21b. The groove 23a includes a flow passage portion 72c, an inflow portion 73c, and an outflow portion 74c. The flow passage portion 72c includes a main portion 75a having a substantially rectangular shape in plan view and provided with the plurality of fins 24a, and a connecting portion 76a connecting the main portion 75a and the inflow portion 73c. A region where the fins 24a are provided is the heat receiving region 28a where the refrigerant 70 receives heat from the second heat generating component 82. The groove 23b includes a flow passage portion 72d, an inflow portion 73d, and an outflow portion 74d. The flow passage portion 72d includes a main portion 77a having a substantially rectangular shape in plan view and provided with the plurality of fins 24b, and a connecting portion 78a connecting the main portion 77a and the inflow portion 73d. A region where the fins 24b are provided is the heat receiving region 28b where the refrigerant 70 receives heat from the third heat generating component 83. The refrigerant 70 flows from the first member 40 into the inflow portions 73c and 73d, and flows through the flow passage portion 72c and 72d. The refrigerant 70 having flowed through the flow passage portion 72c and the flow passage portion 72d flows out from the outflow portion 74c and the outflow portion 74d to the second member 50. The connecting portion 76a and the connecting portion 78a are different from each other in at least one of the lengths and the widths, for example. The other configurations of the modification of the third embodiment are the same as those of the first embodiment, and thus the description thereof will be omitted.

In the third embodiment, the lower member 21a of the second cold plate 20 has a flow passage portion 72a (first groove) and a flow passage portion 72b (second groove). In the modification of the third embodiment, the lower member 21b of the second cold plate 20 has the flow passage portion 72c (first groove) and a flow passage portion 72d (second groove). The flow passage portions 72a and 72c have the heat receiving region 28a (first heat receiving region) that receives heat from the second heat generating component 82. The flow passage portions 72b and 72d include the heat receiving region 28b (second heat receiving region) that receives heat from the third heat generating component 83. In the third embodiment, the refrigerant 70 flowing in from the first member 40 flows through the flow passage portion 72a and the flow passage portion 72b in parallel toward the heat receiving region 28a and the heat receiving region 28b. In the modification of the third embodiment, the refrigerant 70 flowing in from the first member 40 flows through the flow passage portion 72c and the flow passage portion 72d in parallel toward the heat receiving region 28a and the heat receiving region 28b. Accordingly, the refrigerant 70 flows separately to the flow passage portion 72a and the flow passage portion 72b, or the flow passage portion 72c and the flow passage portion 72d, and thus the flow amount of the refrigerant 70 in each of the heat receiving region 28a and the heat receiving region 28b decreases. Therefore, the boiling phenomenon of the refrigerant 70 can be promoted in the heat receiving regions 28a and 28b, and the cooling performance for the second heat generating component 82 and the third heat generating component 83 can be improved.

In addition, in the third embodiment, as illustrated in FIG. 11A, the lower member 21a of the second cold plate 20 has the inflow portion 73a (third groove) into which the refrigerant 70 flows from the first member 40. The flow passage portions 72a and 72b are connected to the inflow portion 73a, so that the refrigerant 70 flows in parallel toward the heat receiving regions 28a and 28b. This reduces the flow amount of the refrigerant 70 in the heat receiving regions 28a and 28b, and thus the boiling phenomenon can be promoted.

In the third embodiment, as illustrated in FIG. 11A, the connecting portion 76 and the connecting portion 78 are different from each other in at least one of the length and the width. In the modification of the third embodiment, as illustrated in FIG. 11B, the connecting portion 76a and the connecting portion 78a are different from each other in at least one of the lengths and the widths. In this manner, by making at least one of the lengths and the widths of the flow paths of the refrigerant 70 flowing in from the first member 40 to reach the heat receiving regions 28a and 28b different, the pressure loss of the flow path can be adjusted. This makes it possible to adjust the flow rate of the refrigerant 70 flowing through the heat receiving regions 28a and 28b. The connecting portion 76 and the connecting portion 78 may have the same lengths and widths as a result of adjustment of the pressure loss of the flow path. Similarly, the connecting portion 76a and the connecting portion 78a may have the same lengths and widths.

### Fourth Embodiment

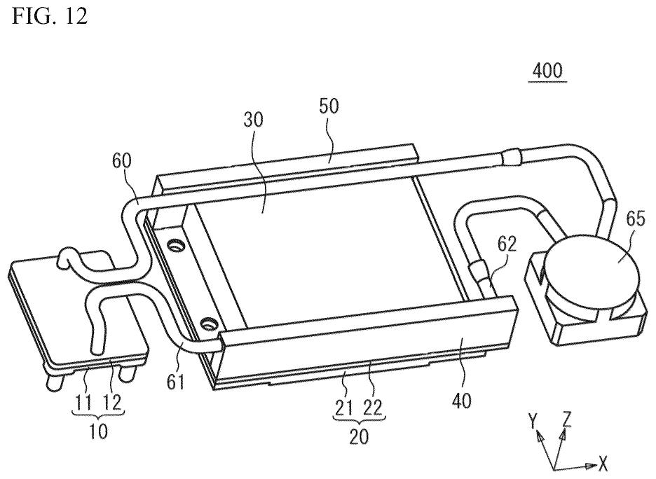

FIG. 12 is a perspective view of a cooling device 400 according to a fourth embodiment. As illustrated in FIG. 12, in the fourth embodiment, a pump 65 is connected to the pipe 60 and the pipe 62. Accordingly, the pump 65 can suck the refrigerant 70 passing through the radiator 30 via the first member 40 and the pipe 62 and causing the refrigerant 70 to flow into the first cold plate 10 via the pipe 60. Therefore, the refrigerant 70 can be circulated among the pump 65, the first cold plate 10, the second cold plate 20, and the radiator 30. The other configurations of the fourth embodiment are the same as those of the first embodiment, and thus the description thereof will be omitted. The number of pumps 65 is not limited to one, and a plurality of pumps 65 may be provided.

### Fifth Embodiment

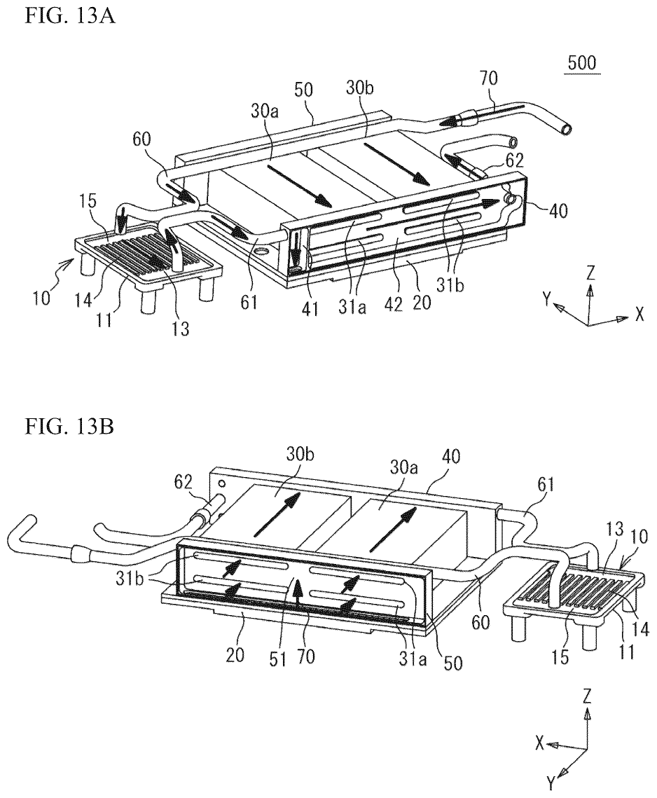

FIG. 13A is a perspective view of a cooling device 500 according to a fifth embodiment as viewed from the −Y direction, and FIG. 13B is a perspective view of the cooling device 500 as viewed from the +Y direction. FIG. 13A illustrates the inside of the first member 40 and the inside of the first cold plate 10 in a see-through manner, and FIG. 13B illustrates the inside of the second member 50 and the inside of the first cold plate 10 in a see-through manner. The flow of the refrigerant 70 is also indicated by arrows. As illustrated in FIGS. 13A and 13B, in the fifth embodiment, a plurality of radiators 30a and a plurality of radiators 30b are provided on the second cold plate 20 side by side in the X-axis direction, respectively. Here, one radiator is a block in which fins and tubes are integrally formed. The refrigerant 70 discharged from the second cold plate 20 flows from the space 51 of the second member 50 into the tubes 31a and 31b of the radiators 30a and 30b. The refrigerant 70 flows through the radiator 30a and 30b, and then flows out from the tubes 31a and 31b into the space 42 of the first member 40. The other configurations of the fifth embodiment and the flow of the refrigerant 70 are the same as those of the first embodiment, and thus the description thereof will be omitted.

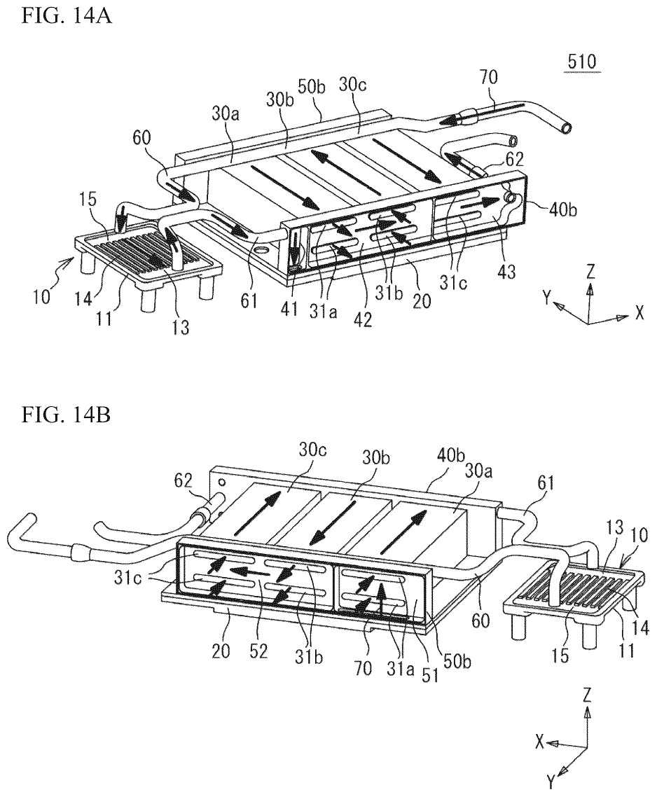

FIG. 14A is a perspective view of a cooling device 510 according to a modification of the fifth embodiment as viewed from the −Y direction, and FIG. 14B is a perspective view of the cooling device 510 as viewed from the +Y direction. FIG. 14A illustrates the inside of a first member 40b and the inside of the first cold plate 10 in a see-through manner, and FIG. 14B illustrates the inside of a second member 50b and the inside of the first cold plate 10 in a see-through manner. The flow of the refrigerant 70 is also indicated by arrows. As illustrated in FIG. 14A, the inside of the first member 40b is divided into the space 41, the space 42, and a space 43. As illustrated in FIG. 14B, the inside of the second member 50b is divided into the space 51 and the space 52.

As illustrated in FIGS. 14A and 14B, in the modification of the fifth embodiment, a plurality of radiators 30a, 30b, and 30c are provided on the second cold plate 20 side by side in the X-axis direction. The refrigerant 70 discharged from the second cold plate 20 flows into the tubes 31a of the radiator 30a from the space 51 of the second member 50b. The refrigerant 70 flows through the radiator 30a and then flows out from the tubes 31a into the space 42 of the first member 40b. The space 42 is also connected to the tubes 31b of the radiator 30b. Therefore, the refrigerant 70 flows from the space 42 into the tubes 31b of the radiator 30b.

The refrigerant 70 flows through the radiator 30b and then flows out from the tubes 31b into the space 52 of the second member 50b. The space 52 is also connected to the tubes 31c of the radiator 30c. Therefore, the refrigerant 70 flows from the space 52 into the tubes 31c of the radiator 30c. The refrigerant 70 flows through the radiator 30c and then flows out from the tubes 31c into the space 43 in the first member 40b. One end of the pipe 62 is connected to the space 43. Therefore, the refrigerant 70 flowed into the space 43 flows through the pipe 62 and is discharged from the other end of the pipe 62. The other configurations of the modification of the fifth embodiment and the flow of the refrigerant 70 are the same as those of the first embodiment, and thus the description thereof will be omitted.

In the fifth embodiment and the modification thereof, the plurality of radiators 30a to 30c are provided on the second cold plate 20 side by side in the X-axis direction (one direction). It may be difficult to dispose the large radiator 30 on the second cold plate 20 from the viewpoint of manufacturing or the like. In such a case, in order to cool the refrigerant 70 by effectively using the space above the second cold plate 20, it is preferable to provide the plurality of radiators 30a to 30c above the second cold plate 20.

In the modification of the fifth embodiment, as illustrated in FIGS. 14A and 14B, the plurality of radiators 30a to 30c are arranged in a direction (X-axis direction) perpendicular to the direction (Y-axis direction) in which the refrigerant 70 flows in the second cold plate 20. The refrigerant 70 flows through the plurality of radiators 30a to 30c arranged in the X-axis direction in order. This improves the cooling effect on the refrigerant 70.

In the fifth embodiment and the modification thereof, the number of radiators is not limited to two or three, and may be four or more.

### Sixth Embodiment

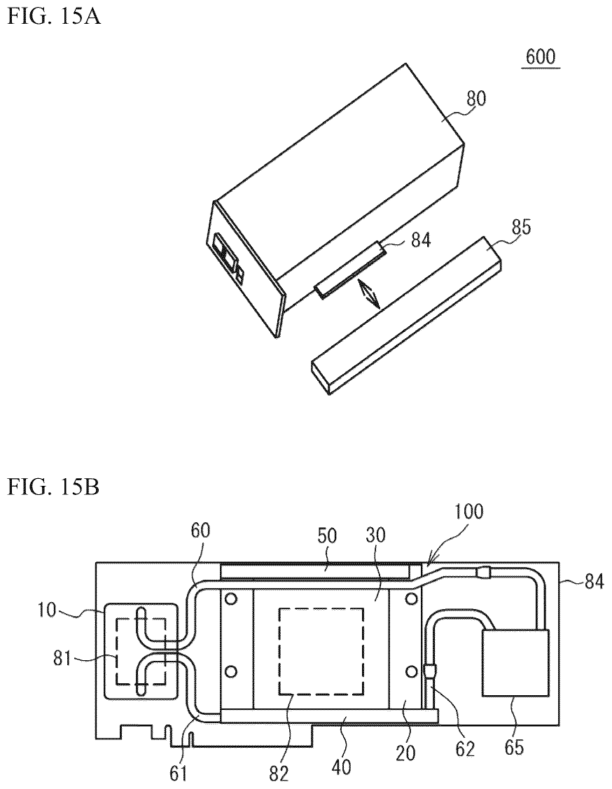

FIG. 15A is an external perspective view of an electronic component 600 according to a sixth embodiment, and FIG. 15B is a plan view of a substrate 84 provided inside a housing 80. As illustrated in FIGS. 15A and 15B, the electronic component 600 according to the sixth embodiment includes the substrate 84 in the housing 80. The electronic component 600 is, for example, a peripheral component interconnect express (PCIe) card, and can be inserted into and removed from a slot 85 of an electronic device such as a computer. The electronic component 600 may be another expansion card or may be a card other than the expansion card.

The first heat generating component 81, the second heat generating component 82, and the pump 65 are provided on the substrate 84. The substrate 84 is, for example, a printed circuit board. The second heat generating component 82 is, for example, a component having a larger heat generation amount than the first heat generating component 81. For example, the first heat generating component 81 is an optical component, and the second heat generating component 82 is an electronic circuit component such as a large scale integration (LSI). The cooling device 100 for cooling the first heat generating component 81 and the second heat generating component 82 is disposed on the substrate 84. Therefore, the cooling device 100 is housed in the housing 80 together with the substrate 84. The pipes 60 and 62 are connected to the pump 65 provided on the substrate 84. The cooling device 100 is described in the first embodiment, and thus the description thereof will be omitted here.

According to the sixth embodiment, the first heat generating component 81, the second heat generating component 82, and the cooling device 100 that cools the first heat generating component 81 and the second heat generating component 82 are provided on the substrate 84. In the cooling device 100, the radiator 30 is provided on the second cold plate 20. Therefore, the cooling device 100 is small in size and can be disposed on the substrate 84. In the cooling device 100, as described in the first embodiment, the refrigerant 70 whose temperature has increased by receiving heat from the first heat generating component 81 in the first cold plate 10 further increases in temperature by receiving heat from the second heat generating component 82 in the second cold plate 20. Therefore, the boiling phenomenon of the refrigerant 70 is promoted in the second cold plate 20, and thus the cooling performance for the second heat generating component 82 is improved.

In the sixth embodiment, the electronic component 600 is an electronic component that can be inserted into and removed from the slot 85 of the electronic device. The slot 85 is, for example, a PCIe slot. The cooling device 100 is small in size, light in weight, and excellent in cooling performance, and thus can be applied to such the electronic component 600.

In addition, in the sixth embodiment, the pump 65 for sucking the refrigerant 70 passing through the radiator 30 and causing the refrigerant 70 to flow into the first cold plate 10 is provided on the substrate 84. Since the cooling device 100 is small, the pump 65 can be provided on the substrate 84.

In the sixth embodiment, the second heat generating component 82 has a larger heat generation amount than the first heat generating component 81. For example, the first heat generating component 81 is an optical component having a small heat generation amount. In this case, since the refrigerant 70 is suppressed from boiling in the first cold plate 10, the boiling in the second cold plate 20 is promoted. Therefore, the cooling performance for the second heat generating component 82 having a large heat generation amount is improved.

In the sixth embodiment, the cooling device provided on the substrate 84 is not limited to the cooling device 100 of the first embodiment, and may be the cooling device of other embodiments and modifications thereof.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A cooling device comprising:
a first cold plate that cools a first heat generating component;
a second cold plate that cools a second heat generating component;
a radiator that is provided on the second cold plate and cools a refrigerant;
a first refrigerant passage that connects the first cold plate and the second cold plate, and causes the refrigerant that received heat from the first heat generating component to flow from the first cold plate into the second cold plate; and
a second refrigerant passage that connects the second cold plate and the radiator and causes the refrigerant that received heat from the second heat generating component to flow from the second cold plate into the radiator.

2. The cooling device according to claim 1, further comprising a first member and a second member provided with the radiator interposed therebetween,
wherein the first member includes the first refrigerant passage and a third refrigerant passage into which the refrigerant flows from the radiator, and
the second member includes the second refrigerant passage.

3. The cooling device according to claim 2, further comprising a pipe connecting the first cold plate and the first member,
wherein the first refrigerant passage is formed by the pipe and a space in the first member.

4. The cooling device according to claim 2,
wherein the first member and the second member are provided from the second cold plate to the first cold plate, and
the first refrigerant passage is formed by a space in the first member.

5. The cooling device according to claim 1,
wherein the second cold plate cools the second heat generating component and the third heat generating component, and includes a first groove and a second groove through which the refrigerant flows in parallel toward a first heat receiving region that receives heat from the second heat generating component and a second heat receiving region that receives heat from the third heat generating component.

6. The cooling device according to claim 5,
wherein the second cold plate includes a third groove into which the refrigerant flows, and
the refrigerant flows in parallel toward the first heat receiving region and the second heat receiving region by connecting the first groove and the second groove to the third groove.

7. The cooling device according to claim 1, further comprising a pump that sucks the refrigerant passed through the radiator and causes the refrigerant to flow into the first cold plate.

8. The cooling device according to claim 1, further comprising a plurality of radiators provided side by side on the second cold plate.

9. The cooling device according to claim 8, wherein the refrigerant flows through the plurality of radiators in order.

10. The cooling device according to claim 1,
wherein the refrigerant performs boiling cooling on the second heat generating component in the second cold plate.

11. An electronic component comprising:
a substrate;
a first heat generating component provided on the substrate;
a second heat generating component provided on the substrate; and
a cooling device provided on the substrate;
wherein the cooling device includes:
a first cold plate that cools the first heat generating component;
a second cold plate that cools the second heat generating component;
a radiator that is provided on the second cold plate and cools a refrigerant;
a first refrigerant passage that connects the first cold plate and the second cold plate and causes the refrigerant that received heat from the first heat generating component to flow from the first cold plate into the second cold plate; and
a second refrigerant passage that connects the second cold plate and the radiator and causes the refrigerant that received heat from the second heat generating component to flow into the radiator.

12. The electronic component according to claim 11,
wherein the electronic component is insertable into and removable from a slot of an electronic device.

13. The electronic component according to claim 11, further comprising a pump provided on the substrate, the pump sucking the refrigerant passed through the radiator and causing the refrigerant to flow into the first cold plate.

14. The electronic component according to claim 12,
wherein the slot is a peripheral component interconnect express (PCIe) slot.

15. The electronic component according to claim 11,
wherein the second heat generating component has a larger heat generation amount than the first heat generating component.

16. The electronic component according to claim 15,
wherein the first heat generating component is an optical component.
